(19) United States
(12) Patent Application Publication
(10) Pub. No.: US 2011/0174376 A1
(43) Pub. Date: Jul. 21, 2011

(54) Monocrystalline Thin Cell

(75) Inventors: Anthony Lochtefeld, Ipswich, MA (US); Jizhong Li, Bordentown, NJ (US); Allen Barnett, Landenberg, PA (US); Donald Stryker, Tyngsboro, MA (US)

(73) Assignee: AMBERWAVE, INC., Salem, NH (US)

(21) Appl. No.: 13/009,844

(22) Filed: Jan. 19, 2011

Related U.S. Application Data
(60) Provisional application No. 61/370,114, filed on Aug. 3, 2010.
(60) Provisional application No. 61/296,289, filed on Jan. 19, 2010.

(51) Int. Cl. H01L 31/0264; H01L 31/02

(52) U.S. Cl. 136/261; 438/57; 257/E31.11

(57) ABSTRACT

A device, system, and method for solar cell construction and bonding/layer transfer are disclosed herein. An exemplary structure of solar cell construction involves providing a monocrystalline donor absorber layer. A conductive bonding layer bonds the absorber layer to a carrier substrate. A porous layer or ion implant may be used to form the donor absorber layer.

### RELATED APPLICATIONS

This application claims the benefit of and priority to U.S. Provisional Application Ser. No. 61/296,289 filed Jan. 19, 2010, and U.S. Provisional Application Ser. No. 61/370,114 filed Aug. 3, 2010 the disclosures of which are hereby incorporated by reference in its entirety.

### TECHNICAL FIELD

The present invention relates to layer transfer and more particularly, relates to layer transfer of thin film monocrystalline silicon onto a substrate.

### BACKGROUND INFORMATION

This invention relates generally to the construction of wafers and substrates used in the optoelectronic and electronic fields. In particular, it relates to a technique of wafer bonding and splitting to facilitate the transfer of thin film semiconductor materials used in making semiconductor substrates for solar cells, LEDs, LDs, optoelectronic integration circuits (OEIC) and microelectromechanical systems (MEMS).

### SUMMARY

The present invention is a novel device, system, and method for a solar cell. An exemplary embodiment involves a monocrystalline solar cell device having a monocrystalline silicon absorber layer and a conductive carrier substrate wherein a conductive bonding layer bonds the absorber layer to the carrier substrate.

Another exemplary embodiment involves a method of monocrystalline solar cell construction. A monocrystalline donor substrate is provided and an ion implant may be performed on a bonding surface of the donor substrate, to define a cleave plane within the donor substrate. A conductive bonding layer may be deposited on the donor substrate and/or a conductive carrier substrate. The donor substrate is bonded to the carrier substrate via the conductive bonding layer. The donor substrate is cleaved at cleave plane. A solar cell may be constructed by means including epitaxial growth on the donated monocrystalline layer, bonded by the conductive bonding layer to the conductive carrier.

Another exemplary embodiment involves a method of monocrystalline solar cell construction. The method may involve providing a monocrystalline silicon donor substrate and forming a porous layer on the silicon donor substrate. A solar cell may be constructed by means including epitaxial growth on the porous layer of the silicon donor substrate. A conductive bonding layer may be deposited on the constructed solar cell and/or a conductive carrier substrate. The donor substrate is bonded to the carrier substrate via the conductive bonding layer. The donor substrate is cleaved at the porous layer. The solar cell, bonded by the conductive bonding layer to the conductive carrier, may undergo further construction.

The present invention is not intended to be limited to a system or method that must satisfy one or more of any stated objects or features of the invention. It is also important to note that the present invention is not limited to the exemplary or primary embodiments described herein. Modifications and substitutions by one of ordinary skill in the art are considered to be within the scope of the present invention, which is not to be limited except by the following claims.

### BRIEF DESCRIPTION OF THE DRAWINGS

These and other features and advantages of the present invention will be better understood by reading the following detailed description, taken together with the drawings wherein:

FIGS. 1A-F are profile diagrams of a device constructed in accordance with an exemplary ion implant and carrier substrate embodiment of the invention.

FIG. 2 is a profile diagram of a completed device in accordance with the exemplary ion implant and carrier substrate embodiment of the invention.

FIG. 3 is a flow chart of exemplary actions used to construct a device in accordance with the exemplary ion implant and carrier substrate embodiment of the invention.

FIGS. 4A-I are profile diagrams of a device constructed in accordance with an exemplary porous layer and carrier substrate embodiment of the invention.

FIG. 5 is a profile diagram of a completed device in accordance with the exemplary porous layer and carrier substrate embodiment of the invention.

FIG. 6 is a flow chart of exemplary actions used to construct a device in accordance with the exemplary porous layer and carrier substrate embodiment of the invention.

FIG. 7 is a flow chart of exemplary actions used to construct a porous layer or layers in accordance with the exemplary porous layer and carrier substrate embodiment of the invention.

FIG. 8 is a flow chart of exemplary actions used to construct a solar cell device in accordance with the exemplary porous layer and carrier substrate embodiment of the invention.

FIGS. 9A-I are profile diagrams of a device constructed in accordance with an exemplary porous layer and carrier substrate with reduced junction area embodiment of the invention.

FIG. 10 is a profile diagram of a completed device in accordance with the exemplary porous layer and carrier substrate with reduced junction area embodiment of the invention.

FIG. 11 is a flow chart of exemplary actions used to construct a solar cell device in accordance with the exemplary porous layer and carrier substrate with reduced junction area embodiment of the invention.

FIGS. 12A-J are profile diagrams of a device constructed in accordance with an exemplary ion implant and carrier substrate with reduced junction area embodiment of the invention.

FIG. 13 is a profile diagram of a completed device in accordance with the exemplary ion implant and carrier substrate with reduced junction area embodiment of the invention.

FIG. 14 is a flow chart of exemplary actions used to construct a device in accordance with the exemplary ion implant and carrier substrate with reduced junction area embodiment of the invention.

### DETAILED DESCRIPTION OF THE PREFERRED EMBODIMENTS

General

At present the world photovoltaic market is dominated by solar cells made from free-standing crystalline silicon wafers, in two forms: multi-crystalline and monocrystalline. Of these, monocrystalline silicon enables higher performance cells, but is also the more expensive technology. Ultra-thin monocrystalline solar cells, with thickness well below 100 microns, may have at least two key advantages. First, silicon material usage is substantially less than for standard monocrystalline silicon solar cells, especially for the case of thin silicon fabrication techniques that avoid the kerf loss (sawing loss) of approximately 150 microns per silicon wafer produced. This alone could reduce monocrystalline silicon solar cell costs significantly. Second, thin monocrystalline silicon solar cells offer the benefit of lower recombination volume, leading to higher open circuit voltages (Voc) and consequently higher cell efficiencies, leading to lower cost per watt.

Despite these benefits, monocrystalline silicon solar cells with silicon thickness below 100 microns have not proved viable thus far. Free-standing silicon wafers below 100 microns may be considered too fragile to be processed with low-cost automated cell processing techniques. So far this approach has demonstrated limited success; typically the solar cell efficiencies are low, and typically non-standard and complicated cell processing techniques are required.

One embodiment of the invention provides a method of making a thin monocrystalline silicon solar cell that includes forming a weak interface in a monocrystalline silicon source substrate via implantation of ions into the monocrystalline silicon source substrate, depositing metal bonding layers on one or both of the source substrate and a conductive carrier substrate, bonding the source and carrier substrates, exfoliating a thin monocrystalline silicon layer from the source substrate such that the thin monocrystalline silicon layer remains bonded to the carrier substrate, using epitaxial deposition of silicon to thicken the monocrystalline silicon layer that is attached to the carrier substrate, and forming a solar cell in the monocrystalline silicon layer by typical solar cell fabrication methods.

Another embodiment of the invention provides a method of making a thin monocrystalline silicon solar cell that includes forming a weak interface in a monocrystalline silicon source substrate via the formation of a porous silicon layer or layers, epitaxially depositing a thin monocrystalline silicon region on top of the porous silicon layer(s), depositing a dielectric passivation layer or layers on the monocrystalline silicon epitaxial region, forming openings within that dielectric passivation layer, depositing metal bonding layers on one or both of the source substrate and a conductive carrier substrate, bonding the source and carrier substrates, exfoliating the thin monocrystalline silicon layer from the source substrate such that the thin monocrystalline silicon layer remains bonded to the carrier substrate, and completing formation of a solar cell in the monocrystalline silicon layer by typical solar cell fabrication methods.

Yet another embodiment of the invention provides a method of making a thin monocrystalline silicon solar cell that includes forming a weak interface in a monocrystalline silicon source substrate via the formation of a porous silicon layer or layers, epitaxially depositing a thin monocrystalline silicon region on top of the porous silicon layer(s), depositing a dielectric passivation layer or layers on the monocrystalline silicon epitaxial region, forming openings within that dielectric passivation layer, forming doped regions in the monocrystalline silicon layer, aligned with the openings in the dielectric passivation layer, depositing metal bonding layers on one or both of the source substrate and a conductive carrier substrate, bonding the source and carrier substrates, exfoliating the thin monocrystalline silicon layer from the source substrate such that the thin monocrystalline silicon layer remains bonded to the carrier substrate, and completing formation of a solar cell in the monocrystalline silicon layer by typical solar cell fabrication methods.

Ion Implant

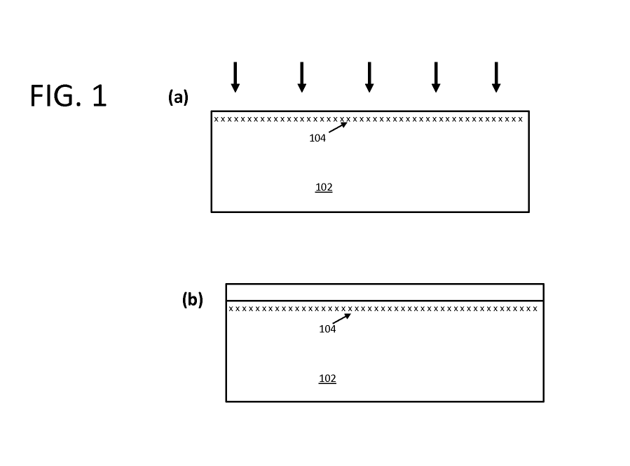

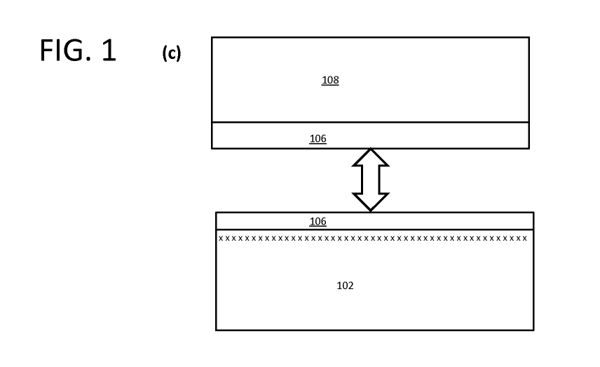

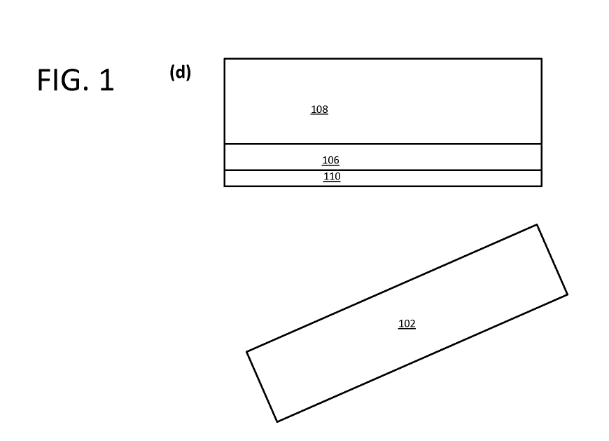

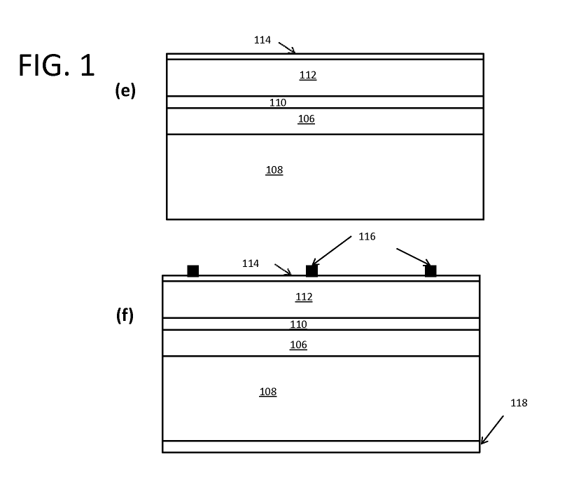

Referring to FIG. 1A-I, an exemplary solar cell device is constructed in accordance with an exemplary ion implant embodiment of the invention. It should be noted that although the various embodiments disclosed herein relate to a solar device, embodiments of the invention are not limited to solar devices and may be used in the construction of various microelectronic and optoelectronic devices.

Referring to FIG. 1A, a monocrystalline silicon donor substrate 102 may be used to construct a first portion of a solar cell. The donor substrate 102 may be, for example, but not limited to, a (100) or (111) surface orientation. The donor substrate 102 may have a thickness of about 150-1000 microns. The diameter of the donor substrate 102 may be, but is not limited to, standard wafer sizes of about 100-300 mm. The donor substrate 102 may be doped p+, with doping above 5×10¹⁸ cm⁻³ for example. The donor substrate 102 is not limited to silicon, and other donor substrates, for example GaAs, InP, or Ge, may be used depending on the intended device to be constructed. According to the exemplary embodiment, an ion-implant with, for example, H and/or He and/or B ions (indicated by arrows) form a cleave plane 104, by methods well known in the art. Ion implant peak depth (corresponding approximately with cleave plane location) may be, for example, but not limited to about 0.1 to 1.0 microns. Such cleave plane 104 may be formed, for example, through the implantation of H₂+ ions to a dose of 2×10¹⁶-8×10¹⁶ cm⁻², at an energy of e.g. 20-200 KeV. An example of conditions used to form a cleave plane in silicon can be found in Tong et al, Appl. Phys. Lett. 72 (1), 5 Jan. 1998, p 49-51.

Referring to FIG. 1B, the conductive bonding layer(s) 106 may be deposited over the ion implanted surface of the donor 102, using, for example, but not limited to, screen printing, evaporation, sputtering, or electro-/electroless-plating. Deposition temperature must be kept below the temperature required to cause a split at the cleave plane 104. Typically this temperature may be 200-400° C., but higher or lower cleave temperatures are possible depending upon the ion implant conditions. The conductive bonding layer(s) 106 provide for (a) subsequent wafer bonding, and may also provide (b) good electrical contact to the p+ silicon, and/or (c) good light reflection. The conductive bonding layer(s) 106 may be metals or a combination of metals, for example, but not limited to, silver (Ag), nickel (Ni), aluminum (Al), chromium (Cr), copper (Cu), titanium (Ti), gold (Au), tin (Sn), indium (In), palladium (Pd), and/or tungsten (W). Metals used may be required to withstand epitaxial temperatures of, for example, about 800-1100° C. involved in possible subsequent processing. Thickness of the conductive bonding layer 106 may be, for example, but not limited to about 20-2000 nm. Note that prior to conductive bonding layer 106 deposition, a metal layer may be deposited to enhance electrical contact to the p+ silicon. For example, silver or aluminum layer deposited by e.g. evaporation or screen printing.

Referring to FIG. 1C, the donor substrate 102 may be bonded to a carrier substrate 108. The carrier substrate 108 may be, for example, inexpensive non-single-crystal metallurgical grade silicon or other suitable material. The carrier substrate 108 may be electrically conductive. The carrier substrate 108 may be of the same or a similar size as the donor substrate 102, and with a thickness in the range of e.g. 100-500 microns. The Coefficient of Thermal Expansion (CTE) of the carrier substrate may be very approximately matched to that of silicon, to allow for subsequent thermal processing steps necessary to form the solar cell, without giving rise to excessive stress in the silicon solar cell regions due to a mismatch between the CTE of silicon and that of the carrier substrate. For example, the CTE of the carrier substrate may be less than about 4-6 ppm/° K. A conductive bonding layer or layers 104 may be deposited on the surface of the carrier substrate 108 to be bonded to the donor substrate 102. The conductive bonding layer(s) 106 may be metals or a combination of metals, for example, but not limited to, silver (Ag), nickel (Ni), aluminum (Al), chromium (Cr), copper (Cu) titanium (Ti), gold (Au), tin (Sn), indium (In), palladium (Pd), and/or tungsten (W). Thickness of the conductive bonding layer 106 may be, for example, about 20-2000 nm. Thermo-compression bonding may be used, or eutectic bonding (for example, Au—Sn interlayers). An example of a metal bonding process may use a titanium layer on the carrier substrate 108 and a titanium layer on the donor substrate 102. The titanium layers may be combined to bond the donor substrate 102 to the carrier substrate 108 as described in, for example, Yu et al., Journal of Electrochemical Society, 154 1 H20-H25 2007. Other methods of metal bonding are described in U.S. Provisional Application Ser. No. 61/370,114 filed Aug. 3, 2010 the disclosures of which are hereby incorporated by reference in its entirety.

Referring to FIG. 1D, the donor substrate 102 may be removed from the thin p+ mono crystalline silicon layer 110 bonded to carrier substrate 108 by annealing the substrate at a temperature of e.g. 200-400° C., forcing cleaving of the donor substrate 102 at the cleave plane layer 104.

Referring to FIG. 1E, the subsequent diagrams are also flipped vertically from previous diagrams with the bonding interface no longer illustrated. An n-doped epitaxial silicon film 112 of thickness e.g. 3-30 microns, with in-situ doping may then be grown on top of the p+ transferred donor substrate using APCVD or LPCVD, with a doping in the range of e.g. 1×10¹⁵ cm⁻³-1×10¹⁷ cm⁻³. The doping species may be e.g. phosphorous or arsenic. This epitaxially grown region forms the base (absorber) of the solar cell. The solar cell construction may then involve epitaxial growth of an n-doped silicon film 114 of thickness about 100-500 nm, with in-situ doping of e.g. >5×10¹⁸ cm⁻³. The doping species could be e.g. phosphorous or arsenic. This layer may later form a Front Surface Field (FSF) and also promote low-resistance contact to the base region of the solar cell.

Referring to FIG. 1F, metal contact lines may be constructed on the surface of the solar cell, for example, via screen printing as is well known in the art. A metal coating on the back of the carrier substrate may also be used to serve as electrical connection to the carrier substrate. This coating could be deposited using, for example, but not limited to, screen printing, evaporation, sputtering, or electro-/electroless-plating.

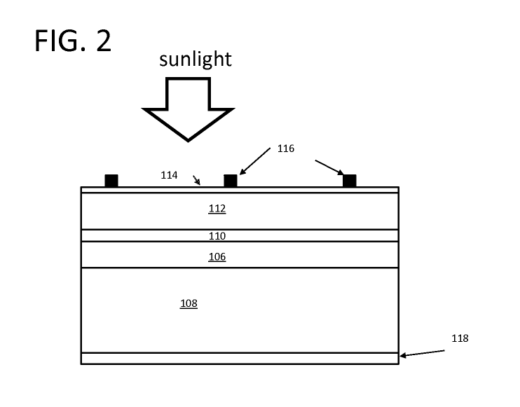

Referring to FIG. 2, the cell on the carrier substrate 108 may have the exemplary basic cell structure. N-type epitaxially grown silicon 112 may provide the absorber region, otherwise known as the base region. The buried p+ layer 102 forms the emitter. Buried conductive layers 106 provide bottom electrical contact to the emitter, plus they may provide light reflection for more effective light absorption in the base region. Light absorption may be restricted to the high quality epitaxial silicon region. The carrier substrate 108 may be of lower quality and may not be part of the active region of the solar cell. This thin silicon cell approach may allow the high electrical conversion efficiency typical of bulk monocrystalline silicon solar cells (where whole silicon wafers of e.g. 150 um thickness or more are used to form the solar cell) but with significant cost savings because of the dramatically reduced usage of the relatively expensive high-quality monocrystalline silicon. This advantage may be realized through the re-use multiple times of the relatively expensive monocrystalline silicon donor wafer. Another advantage of this structure may be a high open circuit voltage, due to the low recombination volume of the thin base region, leading to higher solar cell efficiency.

In an alternative embodiment, the doping types can be reversed. The transferred monocrystalline Si layer could be n+ with a doping of e.g. >5×10¹⁸ cm⁻³, and may ultimately form the emitter. A p-type epitaxial region may be formed, with a doping of e.g. 1×10¹⁵-1×10¹⁷ cm⁻³, ultimately forming the base (absorber) region; this may be followed by a p+ epitaxial region with a doping of e.g. >5×10¹⁸ cm⁻³, to allow good contact to the base region, and potentially also to form a FSF.

After topside wiring for cell interconnect, the cells and/or carrier substrate may be covered with a protective polymer film such as EVA—not shown. It should be noted that the solar cell structure is for illustrative purposes and the invention is not limited to the disclosed structure. Various devices may be constructed and materials can be deposited by a variety of techniques, including thermal or e-beam evaporation, DC or RF sputtering, electroplating, molecular beam epitaxy (MBE), atomic layer deposition (ALD), pulsed-laser deposition (PLD), spin coating, MOCVD, HVPE, liquid phase epitaxy (LPE), screen printing, or any other suitable technique. Materials can be annealed or undergo chemical reactions following deposition, or after additional materials or reactants are deposited or placed in proximity.

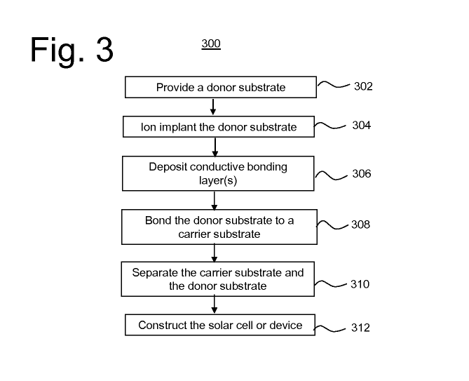

Referring to FIG. 3, construction of the exemplary ion implant and carrier substrate device 300 may include the following actions. The donor substrate is provided (block 302). An ion implant is performed to form a cleave plane in the donor substrate (block 304). A conductive bonding layer(s) may be deposited over the ion implanted surface of the donor and/or the carrier substrate (block 306). The donor substrate is bonded to the carrier substrate (block 308). The carrier substrate and transferred layer are removed from the donor substrate (block 310). The solar cell(s) or device(s) are processed further to completion (block 312) and the separated donor substrate is processed for recycling.

Porous Silicon Layer

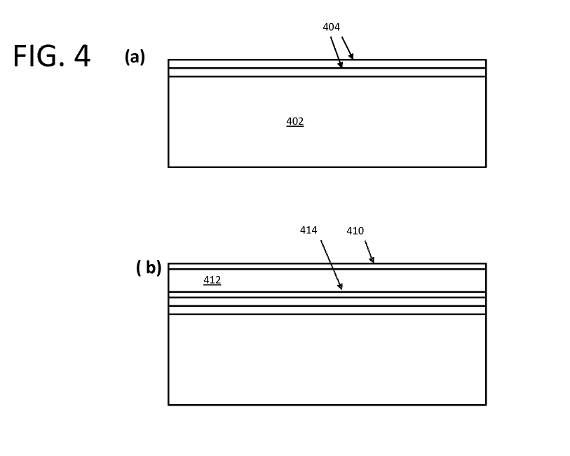

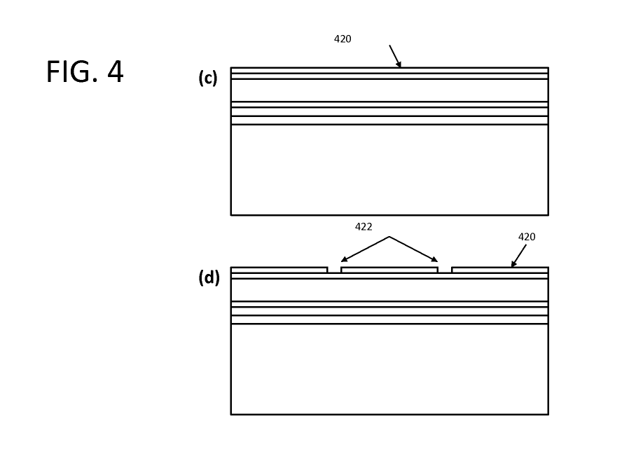

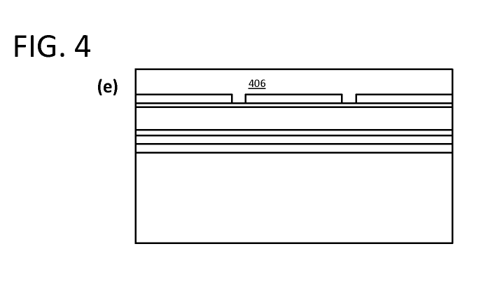

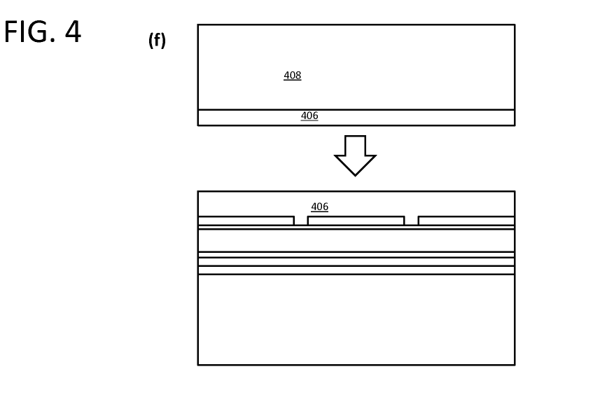

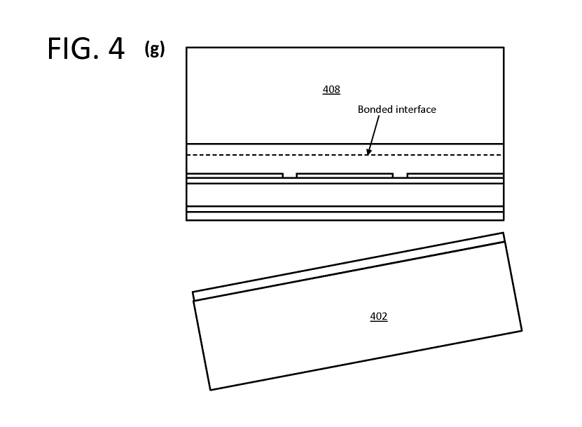

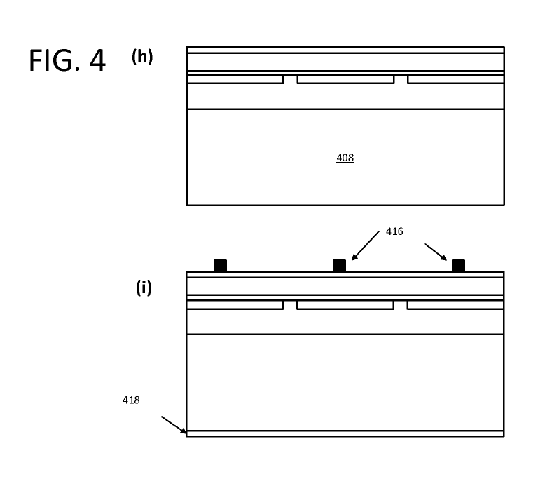

Referring to FIG. 4A-I, an exemplary solar cell device is constructed in accordance with an exemplary porous layer embodiment of the invention. It should be noted that although the various embodiments disclosed herein relate to a solar device, embodiments of the invention are not limited to solar devices and may be used in the construction of various microelectronic and optoelectronic devices. A monocrystalline silicon donor substrate 402 may be used to construct a first portion of a solar cell and the porous region used later for separation. The donor substrate 402 may be, for example, but not limited to, a (100) or (111) surface orientation. The donor substrate 402 may be doped p-type or n+ or alternately may be more lightly doped n-type if it is illuminated during porous silicon formation.

According to the exemplary embodiment, the donor substrate 402 may be p-type and have resistivity below about 10 ohm-cm and a thickness of about 150-1000 microns. The diameter of the donor substrate 402 may be, but is not limited to, standard wafer sizes of 100-300 mm. Dual porous layers 404 are formed on the surface of the donor substrate 402. The top porous layer may have a lower porosity, to serve as a template for subsequent epitaxial growth. The bottom porous layer may have a higher porosity, to allow subsequent splitting. An exemplary approach to creating a splitting plane is known in the art and is described in, for example, Yonehara & Sakaguchi, JSAP Int. July 2001, No. 4, pp. 10-16. The porous layers 404 may also be stabilized via brief thermal oxidation and may also be sealed via anneal under H₂ as described in Yonehara & Sakaguchi.

Referring to FIG. 4B, an n-doped epitaxial silicon film 412 of thickness e.g 100-1000 nm with in-situ doping via e.g. arsenic or phosphorous to a level of >10¹⁸ cm⁻³ may then be grown on top of the porous region using Atmospheric Pressure Chemical Vapor Deposition (APCVD) or Low Pressure Chemical Vapor Deposition (LPCVD), for example, with precursors such as DCS or TCS, at temperatures above e.g. 900 C. This n-type region may serve as a Front Surface Field (FSF) and also promote low-resistance electrical contact to base region of the solar cell. Methods of growing high quality epitaxial regions on porous silicon are well known in the art and may involve a step before epitaxial growth to seal the exposed surface pores, such as, for example, an anneal step under an H₂ ambient. Following this, an n-doped epitaxial film of thickness e.g. 3-30 microns, with in-situ doping via e.g. arsenic or phosphorous to a level of 1×10¹⁵ cm⁻³-1×10¹⁷ cm⁻³ may then be grown; this will serve as the base (absorber) region of the solar cell. Epitaxy may then be continued with growth of an in-situ-doped p+ region 410, for example 100-1000 nm thick, with e.g. boron doping to a level of e.g. 5×10¹⁸ cm⁻³. This p+ region 410 forms the solar cell emitter.

Referring to FIG. 4C, a dielectric passivation layer or layers 420 may be formed over the base of the solar cell. The layer(s) 420 may be, for example, silicon oxide, silicon nitride, or aluminum oxide, formed by means such as thermal oxidation, Plasma Enhanced Chemical Vapor Deposition (PECVD), or atomic layer deposition. The layer(s) 420 may be formed to a thickness of, for example, about 5-1000 nm.

Referring to FIG. 4D, openings 422 may be produced to expose, for example, 1-50% of the solar cell base area. This can be done e.g. by photolithography and wet chemical etch, for example by hydrofluoric acid etch if the dielectric layer is SiO₂. The openings 422 may also be formed by other method known in the art, for example, laser ablation, as for example described S. A. G. D. Correia et al., “Selective Laser Ablation of Dielectric Layers,” (2007), and P. Engelhart, et al., “Laser Structuring for Back Junction Silicon Solar Cells,” Progress in Photovoltaics: Research and Applications, 15 (2007) 237. The openings 422 allow for electrical contact to the emitter region of the solar cell. The openings 422 may be, for example but not limited to, trenches (perpendicular to diagram) or circular, square, or rectangular openings. Opening 422 minimum lateral dimension may be e.g. 0.1-10 microns. Spacing between openings 422 may be e.g. about 1-100 microns.

Referring to FIG. 4E, the conductive bonding layer(s) 406 may be deposited over the passivation layer 420 and openings 422 using, for example, but not limited to, screen printing, evaporation, sputtering, or electro-/electroless plating. The conductive bonding layer(s) 406 provide for (a) subsequent wafer bonding, and may also provide (b) good electrical contact to the silicon, and/or (c) good light reflection. The conductive bonding layer(s) 406 may be metals or a combination of metals, for example, but not limited to, silver (Ag), nickel (Ni), aluminum (Al), chromium (Cr), copper (Cu), titanium (Ti), gold (Au), tin (Sn), indium (In), palladium (Pd), and/or tungsten (W). Thickness of the conductive bonding layer 406 may be e.g. about 20-2000 nm, but is not limited to these thicknesses. Note that prior to conductive bonding layer 406 deposition, a metal layer may be deposited to enhance electrical contact to the p+ silicon emitter. For example, silver or aluminum layer deposited by e.g. evaporation or screen printing

Referring to FIG. 4F, the donor substrate 402, including the first portion of a solar cell, may be bonded to a carrier substrate 408. The carrier substrate 408 may be, for example, inexpensive metallurgical grade silicon, or a metal such as steel or a low-CTE iron-nickel alloy such as Kovar™ or Invar™, or a conductive ceramic such as polycrystalline aluminum titanium nitride, or other suitable material. The carrier substrate 408 may be of the same or a similar size as the donor substrate 402, or it may be larger such as to support multiple solar cells. The carrier substrate 408 may be rigid with a thickness in the range of e.g. 100-500 microns. Alternately, the carrier substrate 408 may be flexible; for example, it may be a steel foil of thickness e.g. below 100 microns. The carrier substrate 408 may be electrically conductive. The Coefficient of Thermal Expansion (CTE) of the carrier substrate may be very approximately matched to that of silicon, to allow for subsequent thermal processing steps necessary to form the solar cell, without giving rise to excessive stress in the silicon solar cell regions due to a mismatch between the CTE of silicon and that of the carrier substrate. For example, the CTE of the carrier substrate may be less than about 6-10 ppm/° K. A conductive bonding layer 406 may be deposited on the surface of the carrier substrate 408 to be bonded to the solar cell and donor substrate 402. The conductive bonding layer(s) 406 may be metals or a combination of metals, for example, but not limited to, silver (Ag), nickel (Ni), aluminum (Al), chromium (Cr), copper (Cu), titanium (Ti), gold (Au), tin (Sn), indium (In), palladium (Pd), and/or tungsten (W). Thickness of the conductive bonding layer 406 could be e.g. about 20-2000 nm. Thermo-compression bonding may be used, or eutectic bonding (for example, Au—Sn interlayers), or non-eutectic solder bonding (e.g. via tin). An example of a metal bonding process may use a titanium layer on the carrier substrate 408 and a titanium layer on the solar cell of the donor substrate 402. The titanium layers may be combined to bond the donor substrate 402 to the carrier substrate 408 as described in, for example, Yu et al., Journal of Electrochemical Society, 154 1 H20-H25 2007. Other methods of metal bonding are described in U.S. Provisional Application Ser. No. 61/370,114 filed Aug. 3, 2010 the disclosures of which are hereby incorporated by reference in its entirety.

Referring to FIG. 4G, the donor substrate 402 may be removed from the first portion of a solar cell bonded to the carrier substrate 408 by cleaving the donor substrate within the porous layers 404. Separation may be via mechanical force alone, or enhanced with various other methods. For example, a wedged device (not shown) may be applied to induce separation at the outer edges of the porous region 404. In another example, separation may be enhanced via application of a high pressure water jet directed at the edge of the porous silicon layers 404, as described in Yonehara & Sakaguchi. In yet another example, a wet acid solution, such as HF/H202, may also be exposed to the porous region 404 to erode the porous region 404 from the edge and enhance separation. In yet another example, for the case of a carrier substrate 408 with a CTE different than that of the silicon donor substrate 402, a thermal anneal may be used to induce stress in the bonded wafer pair, leading to separation within the porous Si layers 404 to relieve the stress. It should be understood that the above examples of separation may be used individually or in various combinations.

Referring to FIG. 4H, once the carrier substrate 408 and solar cell portion have been removed from the donor substrate 402, various post-separation processing of the solar cell portion and/or additional construction of a second portion of the solar cell may occur on the solar cell portion coupled to the carrier substrate 408. The subsequent diagrams are also flipped vertically from previous diagrams with the bonding interface no longer illustrated. Optionally, the porous layer 404 of the portion of the solar cell may be removed with wet acid etch as described in Yonehara & Sakaguchi, or in Nobuhiko Sato et al, Journal of the Electrochemical Society, v. 142 n. 9 p. 3116-22, or via an etch in a KOH (Potassium hydroxide) solution, or via polishing. It may be advantageous to leave some or all of the porous layer 404, as the porous surface's roughness may enhance light capture by the solar cell. The top surface solar cell processing may also include surface roughening (not shown), surface passivation, and deposition of anti-reflection coatings (not shown). Also after splitting, the donor substrates 402 may be processed for reuse in the next wafer production cycle. This processing may include polishing, wet etching, or otherwise cleaning of the cleaved surface for subsequent formation of porous layers in future wafer production cycles.

Referring to FIG. 4I, metal contact lines 416 may be constructed on the surface of the solar cell, for example, via screen printing. A metal coating 418 on the back of the carrier substrate 408 may also be used to enhance electrical connection to the carrier substrate 408, and thus through the carrier substrate 408 to the solar cell p+ emitter region 410. This coating could be deposited using, for example, but not limited to, screen printing, evaporation, sputtering, or electro-/electroless-plating

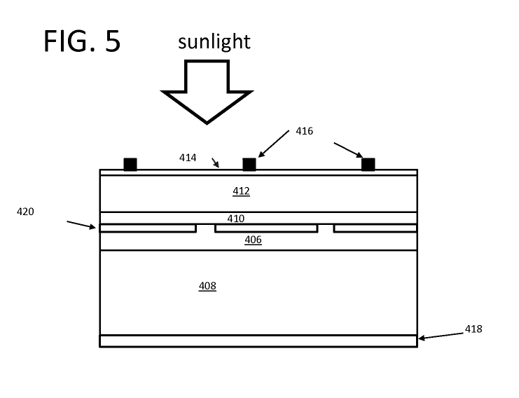

Referring to FIG. 5, the cell on the carrier substrate 408 may have the exemplary basic cell structure. N-type epitaxially grown silicon 412 may provide the solar cell base region. Buried conductive layers 406 provide bottom electrical contact to the p-type emitter region 410, plus may provide light reflection for more effective light absorption in the base region. Light absorption may be largely restricted to the high quality epitaxial silicon region. The carrier substrate 408 may be of lower quality and may not be part of the active region of the solar cell. This thin silicon cell approach may allow the high electrical conversion efficiency typical of bulk monocrystalline silicon solar cells (where whole silicon wafers of e.g. 150 um thickness or more are used to form the solar cell) but with significant cost savings because of the dramatically reduced usage of the relatively expensive high-quality monocrystalline silicon. This advantage may be realized through the re-use multiple times of the relatively expensive monocrystalline silicon donor wafer 402. Another advantage of this structure may be a high open circuit voltage, due to the low recombination volume of the thin base region, leading to higher cell efficiency.

Note that in an alternative embodiment, the configuration of the emitter and base can be reversed. Specifically, the epitaxial growth may begin with a p+ emitter region, followed by the n-type base region, followed by an n+ base contact region. In this case the emitter is on the upper surface of the finished solar cell (facing the sun) and the base contact region is below the base and in contact with the conductive bonding layers.

In another alternative embodiment, the doping types can be reversed, so that the base region is p-type, the emitter region is n+, and the base contact region is p+. For this embodiment, the cell may be configured such that the emitter is on the upper surface of the solar cell (facing the sun) and the base contact region is below the base and in proximity to the conductive bonding layers. Or, the cell may be configured such that the base contact region is on the upper surface of the solar cell (facing the sun) and the emitter region is below the base and in proximity to the conductive bonding layers.

After topside wiring for cell interconnect, the cells and/or carrier substrate may be covered with a protective polymer film such as EVA—not shown. It should be noted that the solar cell structure is for illustrative purposes and the invention is not limited to the disclosed structure. Various devices may be constructed and materials can be deposited by a variety of techniques, including thermal or e-beam evaporation, DC or RF sputtering, electroplating, molecular beam epitaxy (MBE), atomic layer deposition (ALD), pulsed-laser deposition (PLD), spin coating, MOCVD, HVPE, liquid phase epitaxy (LPE), screen printing, or any other suitable technique. Materials can be annealed or undergo chemical reactions following deposition, or after additional materials or reactants are deposited or placed in proximity.

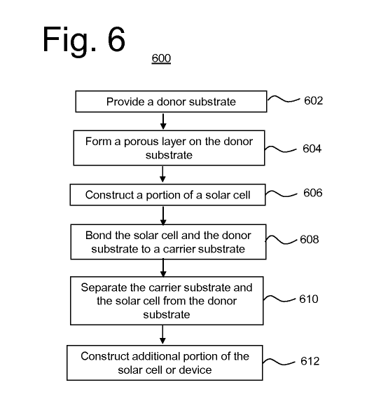

Referring to FIG. 6, construction of the exemplary porous layer and carrier substrate device 600 may include the following actions. The donor substrate is provided (block 602). One or more porous layers are formed on the donor substrate (block 604). A solar cell or device is constructed or partially constructed on top of the porous layer of the donor substrate (block 606). The solar cell or device and donor substrate are bonded to the carrier substrate (block 608). The solar cell or device and carrier substrate are removed from the donor substrate (block 610). The solar cell or device is processed further to completion (block 612) and the separated donor substrates are processed for recycling.

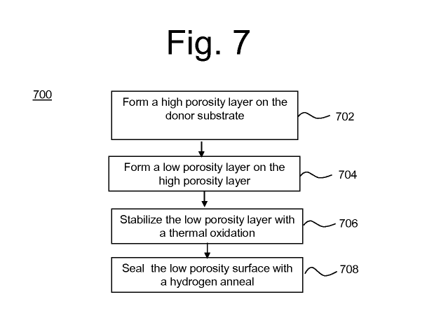

Referring to FIG. 7, construction of the exemplary porous layer(s) 1000 may include the following actions. A layer of high porosity is formed on the donor substrate (block 702). A layer of low porosity is formed on the donor substrate (block 704). The layer of low porosity may be stabilized with a thermal oxidation to serve as a template for subsequent device construction (block 706). The low porosity layer may also be annealed in a hydrogen atmosphere to seal the surface pores and further aid in subsequent device construction (block 708). The porous region is not limited to two layers. Embodiments may include a single porous layer or more layers may be used to provide cleaving at a desired point of separation. For example, a region of high porosity may be sandwiched between two layers of lower porosity.

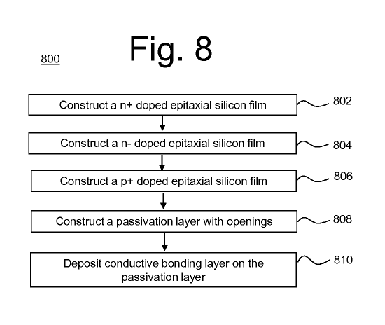

Referring to FIG. 8, construction of the exemplary first portion of a solar cell 800 may include the following actions. An n+ doped epitaxial silicon film is provided on the low porosity template layer of the donor substrate (block 802). An n− doped silicon film is provided on top of the n+ doped epitaxial silicon film (block 804). A p+ doped silicon film is provided on top of the n− doped epitaxial silicon film (block 806). A dielectric passivation layer is optionally provided (block 808). Openings are formed in the passivation layer. The conductive bonding layer is deposited on the passivation layer and on the exposed p+ doped silicon (block 810). Embodiments are not limited to the above structure and may include various additional layers and features.

Porous Silicon Layer with Reduced Junction Area

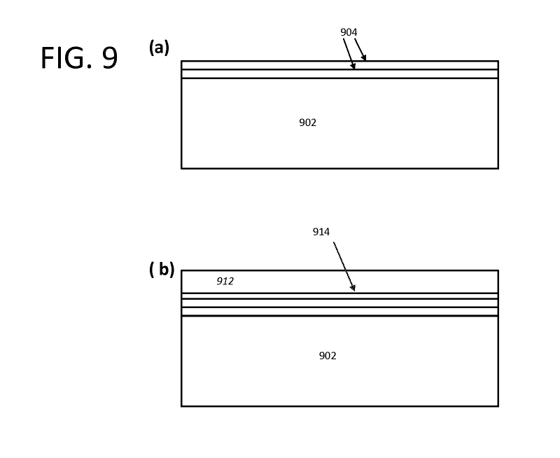

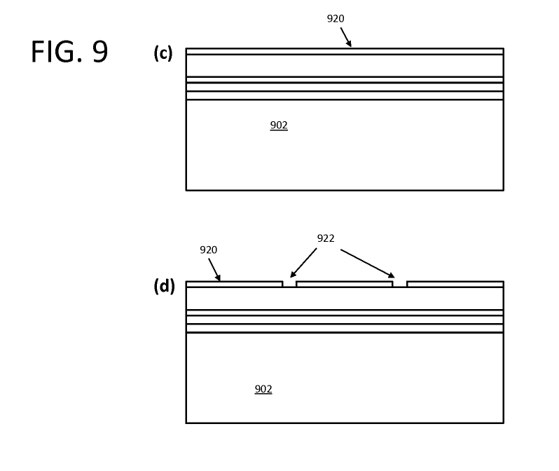

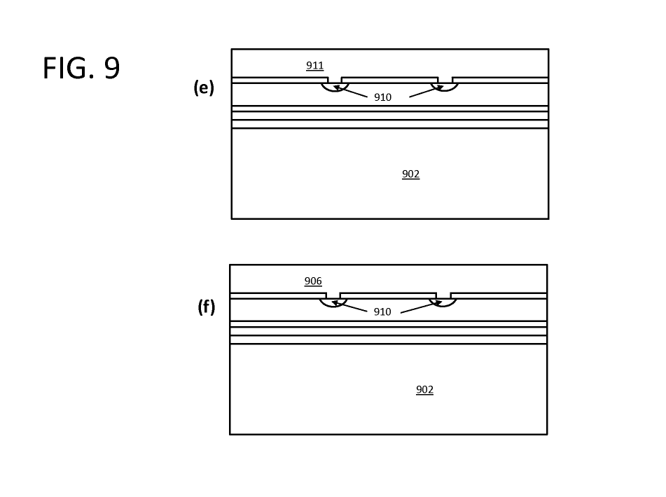

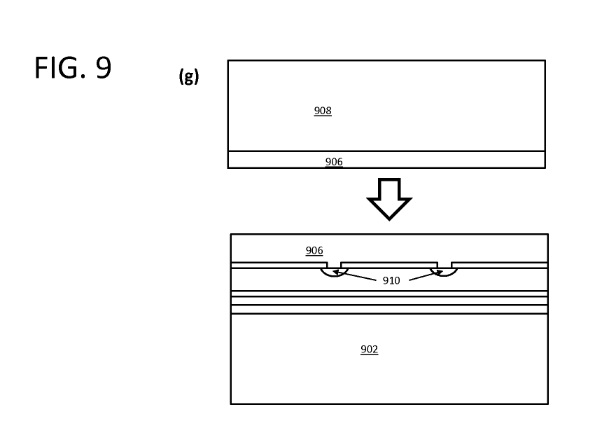

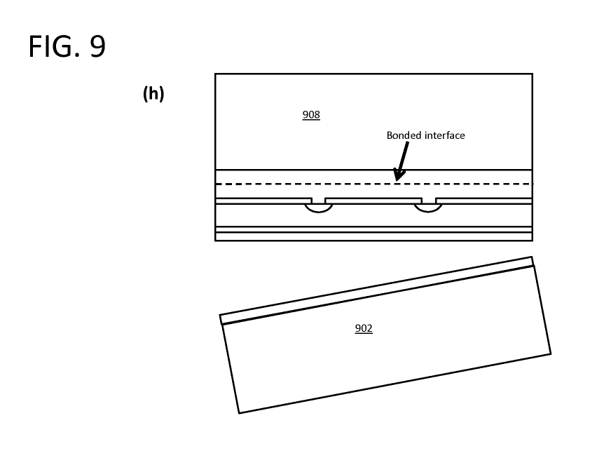

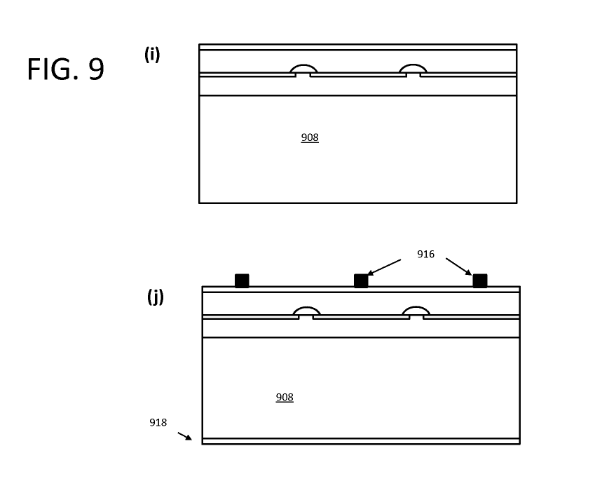

Referring to FIG. 9A-I, an exemplary solar cell device is constructed in accordance with an exemplary porous layer with carrier substrate with reduced junction area embodiment of the invention. It should be noted that although the various embodiments disclosed herein relate to a solar device, embodiments of the invention are not limited to solar devices and may be used in the construction of various microelectronic and optoelectronic devices. Referring to FIG. 9A, a monocrystalline silicon donor substrate 902 may be used to construct a first portion of a solar cell and the porous region 904 used later for separation. The donor substrate 902 may be used similar to the donor substrate of the previously described porous silicon layer embodiment. Dual porous layers 904 are formed on the surface of the donor substrate 902. The top and bottom porous layers are constructed as previously described to allow subsequent splitting.

Referring to FIG. 9B, an n-doped epitaxial silicon film 912 of thickness e.g 100-1000 nm with in-situ doping via e.g. arsenic or phosphorous to a level of >5×10¹⁸ cm⁻³ may then be grown on top of the porous region 904 using Atmospheric Pressure Chemical Vapor Deposition (APCVD) or Low Pressure Chemical Vapor Deposition (LPCVD), for example, with precursors such as DCS or TCS, at temperatures above e.g. 900 C. This n-type region 912 may serve as a Front Surface Field (FSF) and also promote low-resistance electrical contact to base region of the solar cell. Methods of growing high quality epitaxial regions on porous silicon are well known in the art and may involve a step before epitaxial growth to seal the exposed surface pores, such as, for example, an anneal step under an H₂ ambient.

Following this, an n-doped epitaxial film of thickness e.g. 3-30 microns, with in-situ doping via e.g. arsenic or phosphorous to a level of 1×10¹⁵ cm⁻³-1×10¹⁷ cm⁻³ may then be grown; this will serve as the base (absorber) region of the solar cell.

Referring to FIG. 9C, a dielectric passivation layer or layers 920 may be formed over the base of the solar cell. The layer(s) 920 may be, for example, silicon oxide, silicon nitride, or aluminum oxide, formed by means such as thermal oxidation, Plasma Enhanced Chemical Vapor Deposition (PECVD), or atomic layer deposition. The layer(s) 920 may be formed to a thickness of, for example, about 5-1000 nm.

Referring to FIG. 9D, openings 922 may be produced to expose, for example, 1-20% of the solar cell base area. These openings 922 may be designed and patterned to provide reduced junction areas for the solar cells as described in and incorporated herein U.S. patent application Ser. No. 12/795,207 filed on Jun. 7, 2010, entitled “Solar Cell”. This can be done e.g. by photolithography and wet chemical etch, for example by hydrofluoric acid etch if the dielectric layer 920 is SiO₂. The openings 922 may also be formed by other method known in the art, for example, laser ablation, as for example described P. Engelhart, et al., “Laser Structuring for Back Junction Silicon Solar Cells,” Progress in Photovoltaics: Research and Applications, 15 (2007) 237. The openings 922 allow for electrical contact to the emitter region of the solar cell. The openings 922 may be, for example but not limited to, trenches (perpendicular to diagram) or circular, square, or rectangular openings. Opening 922 minimum lateral dimension may be e.g. 0.1-10 microns. Spacing between openings 922 may be e.g. about 1-100 microns.

Referring to FIG. 9E, p+ type dopant regions 910 may be formed within the openings 922 providing p-n junction having reduced areas within the openings 922. The p+ regions 910 may be formed by depositing at source for in-diffusion of p-type dopants 911, for example, Boron-Silicate Glass (BSG) on top of the dielectric layer(s) 920. Deposition can be, for example, via LPCVD or PECVD. An anneal may be used to in-diffuse dopants, forming p-n junction wholly contained within the epitaxial region, and avoiding contact of junction with the n+ epi region. After diffusion of the dopant the dopant source 911 may be removed by, for example a wet HF etch. Embodiments are not limited to solid source doping and other methods of forming p+ doping regions within the openings are possible, for example, gas source diffusion, or alloying the exposed silicon regions with a deposited aluminum layer as described in F. S. Grasso et al, “Characterization of Local Al-Bsf Formation for Perc Solar Cell Structures”, Proceedings of the 25^{th} EU PV SEC (2010, Valencia, Spain), or ion implantation as would be appreciated by one skilled in the art. These p+ regions 910 form the solar cell emitters.

Referring to FIG. 9F, the conductive bonding layer(s) 906 may be deposited over the dielectric/passivation layer(s) 920 and openings 922 using, for example, but not limited to, screen printing, evaporation, sputtering, or electro-/electroless plating. The conductive bonding layer(s) 906 provide for (a) subsequent wafer bonding, and may also provide (b) good electrical contact to the p+ silicon, and/or (c) good light reflection. The conductive bonding layer(s) 906 may be metals or a combination of metals, for example, but not limited to, silver (Ag), nickel (Ni), aluminum (Al), chromium (Cr), copper (Cu), titanium (Ti), gold (Au), tin (Sn), indium (In), palladium (Pd), and/or tungsten (W). Thickness of the conductive bonding layer 906 may be e.g. about 20-2000 nm, but is not limited to these thicknesses. Note that prior to conductive bonding layer 906 deposition, a metal layer may be deposited to enhance electrical contact to the p+ silicon emitter 910. For example, silver or aluminum layer deposited by e.g. evaporation or screen printing.

Referring to FIG. 9G, the donor substrate 902, including the first portion of a solar cell, may be bonded to a carrier substrate 908. The carrier substrate 908 may be, for example, inexpensive metallurgical grade silicon, or a metal such as steel or a low-CTE iron-nickel alloy such as Kovar™ or Invar™, or a conductive ceramic such as polycrystalline aluminum titanium nitride, or other suitable material. The carrier substrate 908 may be electrically conductive. The Coefficient of Thermal Expansion (CTE) of the carrier substrate may be very approximately matched to that of silicon, to allow for subsequent thermal processing steps necessary to form the solar cell, without giving rise to excessive stress in the silicon solar cell regions due to a mismatch between the CTE of silicon and that of the carrier substrate. For example, the CTE of the carrier substrate may be less than about 6-10 ppm/° K. A conductive bonding layer 906 may be deposited on the surface of the carrier substrate 908 to be bonded to the solar cell and donor substrate 902. The conductive bonding layer(s) 906 may be metals or a combination of metals, for example, but not limited to, silver (Ag), nickel (Ni), aluminum (Al), chromium (Cr), copper (Cu), titanium (Ti), gold (Au), tin (Sn), indium (In), palladium (Pd), and/or tungsten (W). Thickness of the conductive bonding layer 906 may be e.g. about 20-2000 nm. Thermo-compression bonding may be used, or eutectic bonding (for example, Au—Sn interlayers), or non-eutectic solder bonding (e.g. via tin). An example of a metal bonding process may use a titanium layer on the carrier substrate 908 and a titanium layer on the solar cell of the donor substrate 902. The titanium layer may be combined to bond the donor substrate 902 to the carrier substrate 908 as described in, for example, Yu et al., Journal of Electrochemical Society, 154 1 H20-H25 2007. Other methods of metal bonding are described in U.S. Provisional Application Ser. No. 61/370,114 filed Aug. 3, 2010 the disclosures of which are hereby incorporated by reference in its entirety.

Referring to FIG. 9H, the donor substrate 902 may be removed from first portion of a solar cell bonded to the carrier substrate 908 by cleaving the donor substrate 902 at the porous layer 904. Various separation methods and enhancement methods may be used as previously described in reference to other embodiments herein.

Referring to FIG. 9I, once the carrier substrate 908 and solar cell portion have been removed from the donor substrate 902, various post-separation processing of the device and/or additional construction of a second portion of the solar cell may occur on the cells coupled to the carrier substrate as previously described in reference to other embodiments herein. The subsequent diagrams are also flipped vertically from previous diagrams with the bonding interface no longer illustrated. Optionally, the porous layer 904 of the portion of the solar cell may be removed with wet acid etch as described in Yonehara & Sakaguchi, or via an etch in a KOH (Potassium hydroxide) solution, or polished. The top surface solar cell processing may also include surface roughening (not shown), surface passivation, or anti-reflection coating (not shown). Also after splitting, the donor substrates 902 may be processed for reuse in the next wafer production cycle. This processing may include polishing or cleaning of the cleaved surface for subsequent formation of porous layers in future wafer production cycles.

Referring to FIG. 9J, metal contact lines 916 may be constructed on the surface of the solar cell, for example, via screen printing. A metal coating 918 on the back of the carrier substrate 908 may also be used to enhance electrical connection to the carrier substrate 908, and thus through the carrier substrate 908 to the solar cell p+ emitter regions 910. This coating could be deposited using, for example, but not limited to, screen printing, evaporation, sputtering, or electro-/electroless-plating.

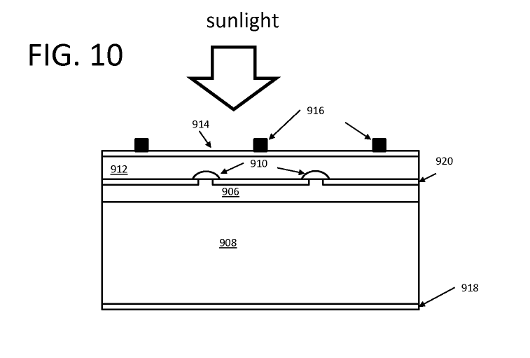

Referring to FIG. 10, the cell on the carrier substrate 908 may have the exemplary basic cell structure. N-type epitaxial grown silicon 912 may provide the base region. Buried conductive layers 906 provide bottom electrical contact to p-type regions 910, plus may provide light reflection for more effective light absorption active region. Light absorption may be largely restricted to the high quality epitaxial silicon region. The carrier substrate 908 may be of lower quality and may not be part of the active region of the solar cell. This thin silicon cell approach may allow the high electrical conversion efficiency typical of bulk monocrystalline silicon solar cells (where whole silicon wafers of e.g. 150 um thickness or more are used to form the solar cell) but with significant cost savings because of the dramatically reduced usage of the relatively expensive high-quality monocrystalline silicon. This advantage may be realized through the re-use multiple times of the relatively expensive monocrystalline silicon donor wafer 902. Another advantage of this structure may be a high open circuit voltage, due to the low recombination volume of the thin base region, leading to higher cell efficiency. Further restricted area of junctions may further increase voltage and efficiency. Other embodiment and alternative construction of devices may be implemented in conjunction with this embodiment and are within the scope of the invention.

After topside wiring for cell interconnect, the cells and/or carrier substrate 908 may be covered with a protective polymer film such as EVA—not shown. It should be noted that the solar cell structure is for illustrative purposes and the invention is not limited to the disclosed structure. Various devices may be constructed and materials can be deposited by a variety of techniques, including thermal or e-beam evaporation, DC or RF sputtering, electroplating, molecular beam epitaxy (MBE), atomic layer deposition (ALD), pulsed-laser deposition (PLD), spin coating, MOCVD, HVPE, liquid phase epitaxy (LPE), screen printing, or any other suitable technique. Materials can be annealed or undergo chemical reactions following deposition, or after additional materials or reactants are deposited or placed in proximity.

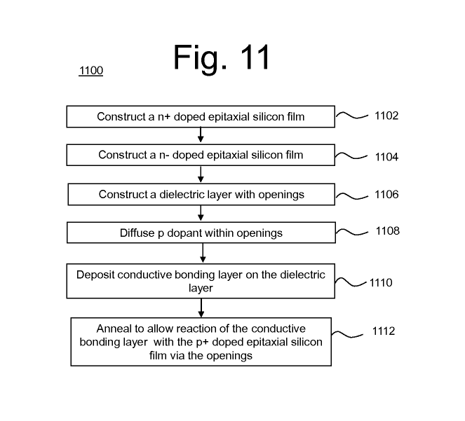

Referring to FIG. 11, construction of the exemplary first portion of a solar cell 1100 may include the following actions. An n+ doped epitaxial silicon film is provided on the low porosity template layer of the donor substrate (block 1102). An n− doped silicon film is provided on top of the n+ doped epitaxial silicon film (block 1104). A dielectric layer is provided with openings to later construct the emitters of the cell as previously described (block 1106). P type dopant is diffused within openings using techniques as previously described herein (block 1108). The conductive bonding layer is deposited on the dielectric layer and/or the openings (block 1110). An optional anneal of the structure is provided to allow the conductive bonding layer to react with the p+ doped silicon film and form the emitters of the cell (block 1112). Embodiments are not limited to the above structure and may include various additional layers and features.

Ion Implant with Reduced Junction Area

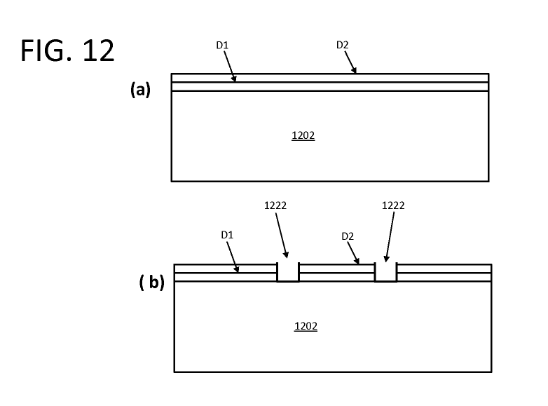

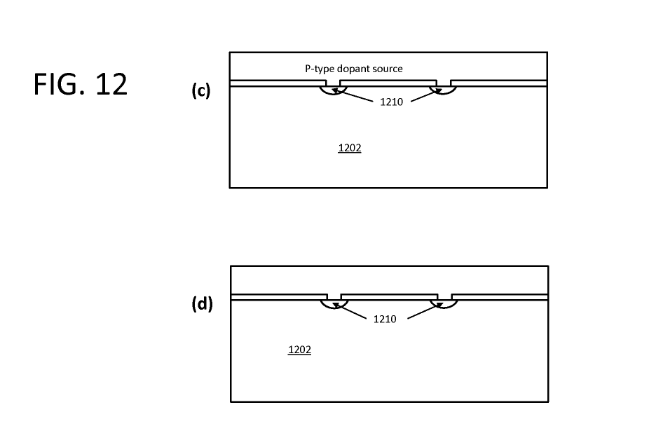

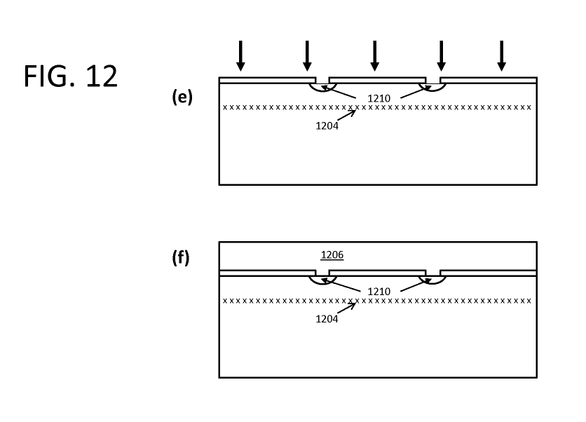

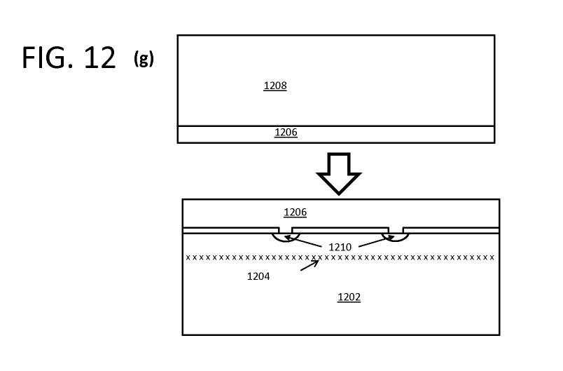

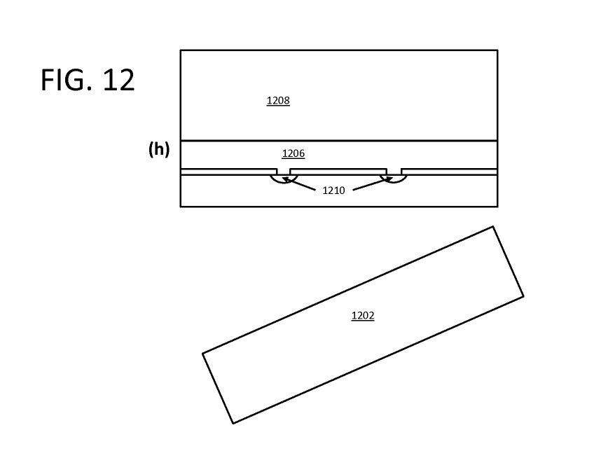

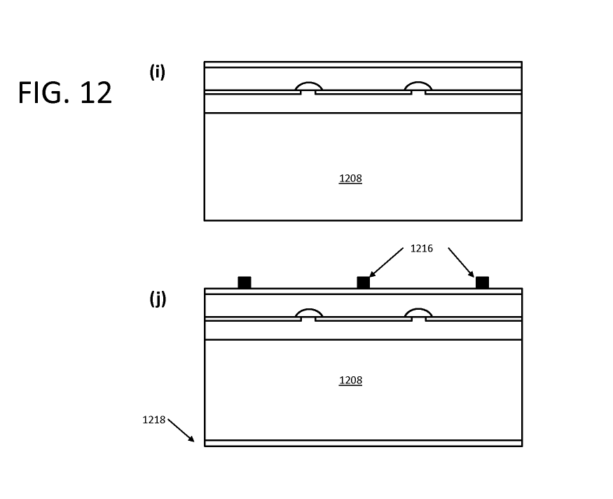

Referring to FIG. 12A-I, an exemplary solar cell device is constructed in accordance with an exemplary ion implant with reduced junction area embodiment of the invention. It should be noted that although the various embodiments disclosed herein relate to a solar device, embodiments of the invention are not limited to solar devices and may be used in the construction of various microelectronic and optoelectronic devices.

Referring to FIG. 12A, a monocrystalline silicon donor substrate 1202 may be used to construct a first portion of a solar cell. The donor substrate 1202 may be used similar to the donor substrate 1202 of the previously described ion implant embodiment. Dual dielectric layers (D1 and D2) may be grown on the donor substrate 1202. The dual dielectric layers may be, for example, SiNx on SiO₂. The dual dielectric layers may be grown using APCVD or LPCVD at a thickness, for example, of about 5-50 nm for D1 and about 0.5-2 microns for D2. Dielectric layer D2 may be selected to be thick enough to mask subsequent dopant in-diffusion.

Referring to FIG. 12B, openings 1222 may be designed and patterned to provide reduced junction areas for the solar cells as described in and incorporated herein U.S. patent application Ser. No. 12/795,207 filed on Jun. 7, 2010, entitled “Solar Cell”. This can be done e.g. by photolithography and wet chemical etch, for example by hydrofluoric acid etch if the dielectric layer is SiO₂. The openings 1222 may also be formed by other method known in the art, for example, laser ablation, as for example described in A. G. D. Correia et al., “Selective Laser Ablation of Dielectric Layers,” (2007), and P. Engelhart, et al., “Laser Structuring for Back Junction Silicon Solar Cells,” Progress in Photovoltaics: Research and Applications, 15 (2007) 237.The openings 1222 may be, for example but not limited to, trenches (perpendicular to diagram) or circular, square, or rectangular openings. Opening 1222 minimum lateral dimension may be e.g. 0.1-10 microns. Spacing 1222 between openings may be e.g. about 1-100 microns.

Referring to FIG. 12C, p+ type dopant regions 1210 may be formed within the openings 1222 providing p-n junction having reduced areas within the openings 1222. The p+ regions 1210 may be formed by depositing a source for in-diffusion of p-type dopants 1211, for example, Boron-Silicate Glass (BSG) on top of the dielectric layer(s) 1220. Deposition can be, for example, via LPCVD or PECVD. An anneal may be used to in-diffuse dopants, forming p-n junction wholly contained within the epitaxial region, and avoiding contact of junction with the n+ epi region. After diffusion of the dopant the dopant source may be removed by, for example a wet HF etch. Embodiments are not limited to solid source doping and other methods are possible, for example, ion implantation as would be appreciated by one skilled in the art. These p+ regions 1210 form the solar cell emitters.

Referring to FIG. 12D, dielectric layer D2 is removed. In the example provided wherein the D1 dielectric layer is SiO₂ and the D2 dielectric layer is SiNx, this removal can be via wet etch via hot phosphoric acid, which will selectively stop on SiO₂ and on the exposed Si regions within the openings 1222.

Referring to FIG. 12E, an ion-implant with, for example, H and/or He and/or B ions (indicated by arrows) form a cleave plane 1204, by methods well known in the art. Since dielectric layer D1 is relatively thin, there may be little difference in implant depth between covered and uncovered regions, allowing the cleave plane to be relatively continuous. Ion implant peak depth (corresponding approximately with cleave plane 1204 location) may be, for example, but not limited to about 0.1 to 1.0 microns and selected deeper than the p-n junction depth. Such a cleave plane 1204 may be formed, for example, through the implantation of H₂+ ions to a dose of 2×10¹⁶-8×10¹⁶ cm⁻², at an energy of e.g. 20-200 KeV. An example of conditions used to form a cleave plane in silicon can be found in Tong et al, Appl. Phys. Lett. 72 (1), 5 Jan. 1998, p 49-51.

Referring to FIG. 12F, the conductive bonding layer(s) 1206 may be deposited over the ion implanted surface of the donor 1202 and dielectric layer D1 and openings 1222, using, for example, but not limited to, screen printing, evaporation, sputtering, or electro-/electroless-plating. Deposition temperature must be kept below the temperature required to cause a split at the cleave plane 1204. Typically this temperature may be 200-400° C., but higher or lower cleave temperatures are possible depending upon the ion implant condition. The conductive bonding layer(s) 1206 provide for (a) subsequent wafer bonding, and may also provide (b) good electrical contact to the p+ silicon (c) good light reflection. The conductive bonding layer(s) 1206 may be metals or a combination of metals, for example, but not limited to, silver (Ag), nickel (Ni), aluminum (Al), chromium (Cr), copper (Cu), titanium (Ti), gold (Au), tin (Sn), indium (In), palladium (Pd), and/or tungsten (W). Metals used may be required to withstand epitaxial temperatures of, for example, about 800-1100° C. involved in possible subsequent processing. Thickness of the conductive bonding layer 1206 may be, for example, but not limited to about 20-2000 nm. Note that prior to conductive bonding layer 1206 deposition, a metal layer may be deposited to enhance electrical contact to the p+ silicon 1210. For example, silver or aluminum layer deposited by e.g. evaporation or screen printing.

Referring to FIG. 12G, the donor substrate 1202 may be bonded to a carrier substrate 1208. The carrier substrate 1208 may be, for example, inexpensive non-single-crystal metallurgical grade silicon or other suitable material. The carrier substrate 1208 may be electrically conductive. A conductive bonding layer or layers 1206 may be deposited on the surface of the carrier substrate 1208 to be bonded to the donor substrate 1202. The conductive bonding layer(s) 1206 may be metals or a combination of metals, for example, but not limited to, silver (Ag), nickel (Ni), aluminum (Al), chromium (Cr), copper (Cu), titanium (Ti), gold (Au), tin (Sn), indium (In), palladium (Pd), and/or tungsten (W). Thickness of the conductive bonding layer 1206 may be, for example, about 20-2000 nm. After bonding, small voids may remain in conductive bonding layers 1206. The small voids may correspond to the openings in the dielectric layer D1. These are not expected to cause problems and may remain in the conductive layer 1206. Various bonding methods and enhancement methods may be used as previously described in reference to other embodiments herein.

Referring to FIG. 12H, the donor substrate 1202 may be removed from the monocrystalline silicon layer bonded to carrier substrate 1208 by annealing the substrate at a temperature of e.g. 200-400° C., forcing cleaving of the donor substrate 1202 at the cleave plane layer 1204.

Referring to FIG. 12I, the subsequent diagrams are also flipped vertically from previous diagrams with the bonding interface no longer illustrated. An n-doped epitaxial silicon film 1212 of thickness e.g. 3-30 microns, with in-situ doping may then be grown on top of the p+ transferred donor substrate using APCVD or LPCVD, with a doping in the range of e.g. 1×10¹⁵ cm⁻³-1×10¹⁷ cm⁻³. The doping species may be e.g. phosphorous or arsenic. This epitaxially grown region forms the base (absorber) of the solar cell. The solar cell construction may then involve epitaxial growth of an n-doped silicon film of thickness about 100-1000 nm, with in-situ doping of e.g. >5×10¹⁸ cm⁻³. The doping species could be e.g. phosphorous or arsenic. This layer may later form a Front Surface Field (FSF) and also promote low-resistance contact to the top of the solar cell.

Referring to FIG. 12J, metal contact lines 1216 may be constructed on the surface of the solar cell, for example, via screen printing as is well known in the art. A metal coating 1218 on the back of the carrier substrate 1208 may also be used to serve as electrical connection to the carrier substrate 1208. This coating 1218 could be deposited using, for example, but not limited to, screen printing, evaporation, sputtering, or electro-/electroless-plating

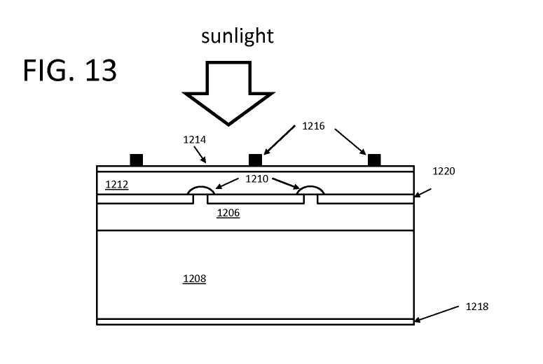

Referring to FIG. 13, the cell on the carrier substrate 1208 may have the exemplary basic cell structure. N-type epitaxially grown silicon 1212 may provide the absorber region, otherwise known as the base region. The buried p+ layer 1210 forms the emitter. Buried conductive layers 1206 provide bottom electrical contact to the emitter, plus they may provide light reflection for more effective light absorption in the base region. Light absorption may be restricted to the high quality epitaxial silicon region. The carrier substrate 1208 may be of lower quality and may not be part of the active region of the solar cell. This thin silicon cell approach may allow the high electrical conversion efficiency typical of bulk monocrystalline silicon solar cells (where whole silicon wafers of e.g. 150 um thickness or more are used to form the solar cell) but with significant cost savings because of the dramatically reduced usage of the relatively expensive high-quality monocrystalline silicon. This advantage may be realized through the re-use multiple times of the relatively expensive monocrystalline silicon donor wafer 1202. Another advantage of this structure may be a high open circuit voltage, due to the low recombination volume of the thin base region, leading to higher solar cell efficiency. Further restricted area of junctions may further increase voltage and efficiency. Other embodiment and alternative construction of devices may be implemented in conjunction with this embodiment and are within the scope of the invention.

After topside wiring for cell interconnect, the cells and/or carrier substrate may be covered with a protective polymer film such as EVA—not shown. It should be noted that the solar cell structure is for illustrative purposes and the invention is not limited to the disclosed structure. Various devices may be constructed and materials can be deposited by a variety of techniques, including thermal or e-beam evaporation, DC or RF sputtering, electroplating, molecular beam epitaxy (MBE), atomic layer deposition (ALD), pulsed-laser deposition (PLD), spin coating, MOCVD, HVPE, liquid phase epitaxy (LPE), screen printing, or any other suitable technique. Materials can be annealed or undergo chemical reactions following deposition, or after additional materials or reactants are deposited or placed in proximity.

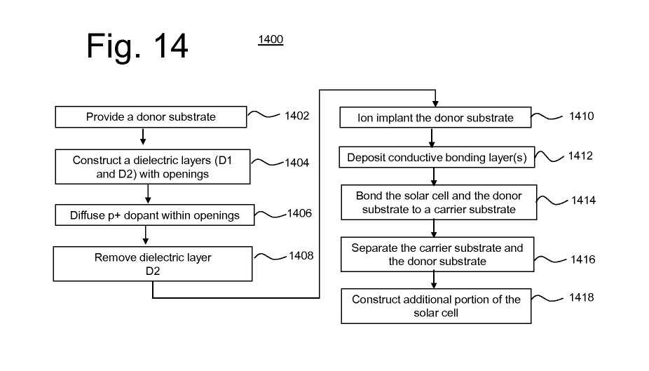

Referring to FIG. 14, construction of the exemplary ion implant and carrier substrate with reduced junction area device 1400 may include the following actions. The donor substrate is provided (block 1402). Dielectric layers D1 and D2 are constructed with openings (block 1404). P type dopant is diffused within openings using techniques as previously described herein (block 1406). The dielectric layer D2 is removed (block 1408). An ion implant is performed to form a cleave plane in the donor substrate (block 1410). A conductive bonding layer(s) may be deposited over dielectric layer D1 and openings of the ion implanted surface of the donor substrate (block 1412). The donor substrate is bonded to the carrier substrate (block 1414). The carrier substrate and transferred layer are removed from the donor substrate (block 1416). The solar cell(s) or device(s) are processed further to completion (block 1418) and the separated donor substrate is processed for recycling.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of this invention are presented for purposes of illustration and description. They are not intended to be exhaustive or to limit the invention to the precise forms disclosed; obviously many modifications and variations are possible in view of the above teachings. The embodiments were chosen and described in order to best explain the principles of the invention and its practical applications. These procedures will enable others, skilled in the art, to best utilize the invention and various embodiments with various modifications. It is intended that the scope of the invention be defined by the following claims and their equivalents. Modifications and substitutions by one of ordinary skill in the art are considered to be within the scope of the present invention, which is not to be limited except by the following claims.

The invention claimed is:

1. A monocrystalline solar cell device, comprising:
a monocrystalline silicon absorber layer and
a conductive carrier substrate wherein a conductive bonding layer bonds the absorber layer to the carrier substrate.

2. The monocrystalline solar cell device of claim 1, wherein the silicon absorber layer is less than about 100 microns thick.

3. The monocrystalline solar cell device of claim 1, wherein the absorber layer and conductive bonding layer produces an ohmic contact.

4. The monocrystalline solar cell device of claim 1, wherein the conductive carrier substrate has a coefficient of thermal expansion of below about 10 ppm/° K.

5. The monocrystalline solar cell device of claim 1, wherein the conductive carrier substrate has a coefficient of thermal expansion of below about 6 ppm/° K.

6. The monocrystalline solar cell device of claim 1, wherein the conductive bonding layer is comprised of a metal layer.

7. The monocrystalline solar cell device of claim 1, wherein the conductive bonding layer includes a layer of titanium sandwiched between a layers of chromium.

8. The monocrystalline solar cell device of claim 1, further comprising:
a passivation layer disposed between the absorber layer and the conductive bonding layers.

9. The monocrystalline solar cell device of claim 8, wherein the passivation layer includes openings providing electrical conductivity between the absorber layer and the conductive bonding layers.

10. The monocrystalline solar cell device of claim 8, wherein the passivation layer is selected from a group consisting of silicon nitride, silicon oxide, aluminum oxide, and/or amorphous silicon.

11. The monocrystalline solar cell device of claim 1, further comprising
a dielectric layer with openings between the absorber layer and the conductive bonding layers wherein the openings produce a limited p-doped region resulting in a limited junction areas of the solar cell device.

12. The monocrystalline solar cell device of claim 1, wherein the absorber layer is between 5 and 30 microns thick.

13. A method of monocrystalline solar cell construction, the method comprising the actions of:
providing a monocrystalline donor substrate;
performing an ion implant on a bonding surface of the donor substrate;
depositing a conductive bonding layer on the donor substrate and/or a conductive carrier substrate;
bonding the donor substrate to the carrier substrate via the conductive bonding layer;
cleaving the donor substrate at the ion implant; and
constructing a solar cell by epitaxial growth on a donated monocrystalline layer bonded by the conductive bonding layer to the conductive carrier.

14. The method of solar cell construction of claim 13, wherein the donated monocrystalline layer is less than about 100 microns thick.

15. The method of solar cell construction of claim 13, further comprising the action of:
depositing a passivation layer between the donor substrate and the conductive bonding layers.

16. The method of solar cell construction of claim 13, further comprising
producing a dielectric layer with openings between the donated monocrystalline layer and the conductive bonding layers wherein the openings produce a limited p-doped region resulting in a limited junction areas of the solar cell device.

17. A method of monocrystalline solar cell construction, the method comprising:
providing a monocrystalline silicon donor substrate;
forming a porous layer on the silicon donor substrate;
constructing a solar cell by epitaxial growth on the porous layer of the silicon donor substrate;
depositing a conductive bonding layer on the constructed solar cell and/or a conductive carrier substrate;
bonding the donor substrate to the carrier substrate via the conductive bonding layer; and
cleaving the donor substrate at the porous layer.

18. The method of solar cell construction of claim 17, further comprising the action of:
depositing a passivation layer between the donor substrate and the conductive bonding layers.

19. The method of solar cell construction of claim 17, further comprising
producing a dielectric layer with openings between the constructed solar cell and the conductive bonding layers wherein the openings produce a limited p-doped region resulting in a limited junction areas of the solar cell device.

20. The method solar cell construction of claim 17, wherein the action of forming the porous layer further comprises producing a first low porosity layer to serve as a template for constructing the first portion of the solar cell, and a high porosity layer at which the action of separating the carrier substrate and the first portion of the solar cell from the silicon donor substrate occurs.
